(19) United States
(12) Patent Application Publication
(10) Pub. No.: US 2026/0223283 A1
(43) Pub. Date: Jul. 30, 2026

(54) OPTICAL CIRCUIT BOARD, OPTICAL COMPONENT MOUNTING STRUCTURE, AND MANUFACTURING METHOD FOR OPTICAL CIRCUIT BOARD

(71) Applicant: KYOCERA Corporation, Kyoto-shi, Kyoto (JP)

(72) Inventor: Takuya KITAINUI, Yasu-shi, Shiga (JP)

(73) Assignee: KYOCERA Corporation, Kyoto-shi, Kyoto (JP)

(21) Appl. No.: 19/143,709

(22) PCT Filed: Dec. 21, 2023
(86) PCT No.: PCT/JP2023/045840

§ 371 Date: Jun. 26, 2025

(30) Foreign Application Priority Data
Dec. 28, 2022 (JP) 2022-211173

(51) Int. Cl. H05K 1/02; G02B 6/10

(52) U.S. Cl. CPC H05K 1/0274; G02B 6/10; H05K 2201/10121

(57) ABSTRACT

An optical circuit board according to the present disclosure includes a wiring board including a first upper surface and an optical waveguide located on the first upper surface and extending toward a center from a peripheral edge of the wiring board. The optical waveguide includes a lower cladding, a core, and an upper cladding in this order from the first upper surface side. The core extends on a second upper surface of the lower cladding, and the upper cladding covers the second upper surface and the core. The optical waveguide includes a recessed portion with the lower cladding as a bottom surface and including a recessed portion opening open to a third upper surface and a side surface of the optical waveguide. An end surface of the core is exposed on a first wall surface of wall surfaces of the recessed portion.

### TECHNICAL FIELD

The present disclosure relates to an optical circuit board, an optical component mounting structure using an optical circuit board, and a manufacturing method for an optical circuit board.

### BACKGROUND OF INVENTION

An optical fiber that can transmit large amounts of data at high speed has recently been used for information communication. An optical signal is transmitted and received between the optical fiber and an optical component. Such an optical component is mounted on, for example, an optical circuit board. The optical circuit board is provided with an optical waveguide. The optical signal is transmitted and received via the optical waveguide.

When the optical waveguide is processed, end surfaces (a lower cladding end surface, an upper cladding end surface, and a core end surface) are cut using a dicer or the like. Thus, as described in Patent Document 1, the lower cladding end surface, the upper cladding end surface, and the core end surface are flush with each other. One end surface of the optical waveguide is connected to an optical connector by an adhesive.

### CITATION LIST

### Patent Literature

Patent Document 1: JP 2001-281479 A

### SUMMARY

### Solution to Problem

An optical circuit board according to the present disclosure includes a wiring board including a first upper surface and an optical waveguide located on the first upper surface and extending from a peripheral edge of the wiring board toward a center of the wiring board. The optical waveguide includes a lower cladding, a core, and an upper cladding in this order from the first upper surface side. The core extends on a second upper surface of the lower cladding, and the upper cladding covers the second upper surface and the core. The optical waveguide includes a recessed portion with the lower cladding as a bottom surface and including a recessed portion opening open to a third upper surface and a side surface of the optical waveguide. An end surface of the core is exposed on a first wall surface of wall surfaces of the recessed portion that is spaced apart from the peripheral edge of the wiring board. A first groove located below the end surface of the core is located in the bottom surface of the recessed portion.

An optical component mounting structure according to the disclosure includes the optical circuit board described above and an optical component mounted on the optical circuit board described above.

A manufacturing method for an optical circuit board according to the present disclosure includes preparing the wiring board including the first upper surface, forming the optical waveguide from the peripheral edge of the first upper surface toward a center of the first upper surface, the optical waveguide including the lower cladding including the second upper surface, the core, and the upper cladding and including an end portion at the peripheral edge of the wiring board, preparing a laser device converging at a first angle with respect to an irradiation axis, adjusting an angle between a third upper surface of the optical waveguide and a laser irradiation axis to 90 degrees+the first angle, and forming a recessed portion with the lower cladding as a bottom surface and including a recessed portion opening continuously open to both the third upper surface and a side surface of the optical waveguide by irradiating an end portion of the optical waveguide with the laser. During the formation of the recessed portion, the end surface of the core is exposed on a first wall surface of the wall surfaces of the recessed portion, that is spaced apart from the peripheral edge of the wiring board, and a first groove located continuously with the first wall surface is formed in the bottom surface of the recessed portion below the end surface of the core.

### BRIEF DESCRIPTION OF THE DRAWINGS

FIG. 1 is a plan view illustrating an optical component mounting structure in which an optical component and an electronic component are mounted on an optical circuit board according to an embodiment of the present disclosure.

FIG. 2 is an enlarged explanatory view for illustrating a cross section of a region X illustrated in FIG. 1.

FIG. 3 is a plane perspective view of a region Y illustrated in FIG. 2 as viewed from a direction of an arrow A illustrated in FIG. 2 (however, an optical connector and an adhesive are omitted).

FIG. 4 is an enlarged explanatory view illustrating a cross section taken along a line X-X illustrated in FIG. 3.

FIG. 5 is an enlarged explanatory view illustrating a state in which a recessed portion illustrated in FIG. 3 is filled with an adhesive and an optical connector is connected.

FIG. 6 is a perspective view as viewed from a direction of an arrow B illustrated in FIG. 3.

FIG. 7 is an enlarged explanatory view illustrating another cross section taken along the line X-X illustrated in FIG. 3.

FIG. 8 is explanatory views each for illustrating a process of manufacturing the optical circuit board according to the embodiment of the present disclosure.

FIG. 9 is explanatory views each for illustrating a process of manufacturing the optical circuit board according to the embodiment of the present disclosure.

### DESCRIPTION OF EMBODIMENTS

As described above, one end surface of the optical waveguide is connected to an optical connector by an adhesive. When the connection strength of the adhesive is insufficient, for example, at the time of transportation or the like, misalignment occurs at a connecting surface between the end surface of the optical waveguide and the optical connector. When such a misalignment occurs, the transmission efficiency of the optical signal deteriorates and the transmission loss increases. Furthermore, when the end surfaces of the optical waveguides are flush with each other, the core end surface is likely to come into contact with an external member, and thus scratches may occur on the core end surface. When scratches occur on the core end surface, the transmission efficiency of the optical signal is deteriorated and the transmission loss is increased. Thus, there is a demand for an optical circuit board that is excellent in connection reliability between the optical waveguide and the optical connector and has a small transmission loss.

The optical circuit board according to the present disclosure is excellent in connection reliability between the optical waveguide and the optical connector, has a small transmission loss, and can efficiently transmit the optical signal by having the configuration described in the section of SOLUTION TO PROBLEM.

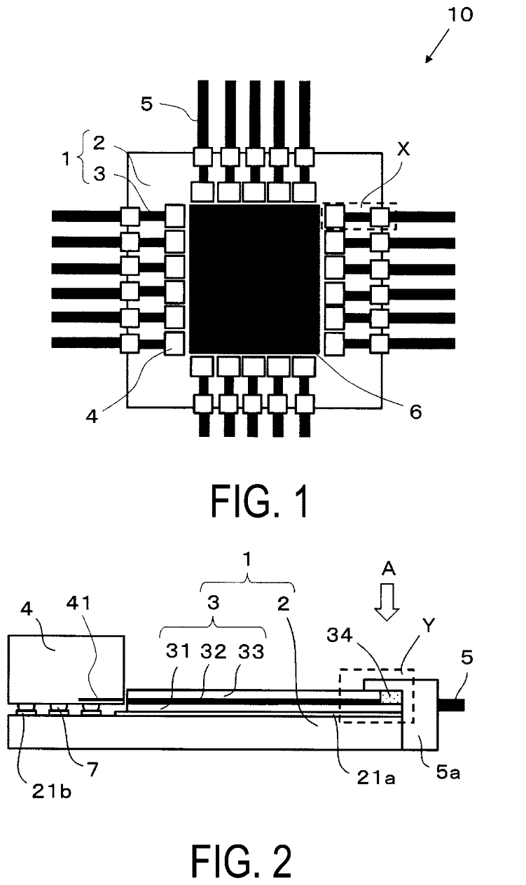

The optical circuit board according to an embodiment of the present disclosure will be described based on FIGS. 1 to 7. FIG. 1 is a plan view illustrating an optical component mounting structure 10 in which an optical component 4 and an electronic component 6 are mounted on an optical circuit board 1 according to the embodiment of the present disclosure.

In the embodiment of the present disclosure, the optical circuit board 1 includes a wiring board 2 and an optical waveguide 3. Examples of the wiring board 2 included in the optical circuit board 1 according to the embodiment include a wiring board typically used for an optical circuit board.

Although not specifically illustrated, the wiring board 2 includes, for example, a core substrate and build-up layers layered on both surfaces of the core substrate. The core substrate is not particularly limited as long as the core substrate is made of a material having an insulation property. Examples of a material with insulation include resins such as epoxy resin, bismaleimide-triazine resin, polyimide resin, and polyphenylene ether resin. Only one of these resins may be used, or two or more of these resins may be used in combination. The core substrate usually includes a through hole conductor for electrically connecting the upper and lower surfaces of the core substrate.

The core substrate may contain a reinforcing material. Examples of the reinforcing material include insulation fabrics such as glass fiber, glass nonwovens, aramid nonwoven, aramid fiber, and polyester fiber. Only one type of the reinforcing material may be used, or two or more types may be used in combination. An inorganic filler made of, for example, silica, barium sulfate, talc, clay, glass, calcium carbonate, or titanium oxide may be dispersed in the core substrate. Only one type of the inorganic filler may be used, or two or more types may be used in combination.

The build-up layer has a structure in which insulation layers and electrical conductor layers are alternately layered. A part of the outermost electrical conductor layer (electrical conductor layer located on the upper surface of the wiring board 2) includes a metal layer 21a in which the optical waveguide 3 is located. The conductor layer is made of a metal such as copper. Similar to the core substrate, the insulation layer included in the build-up layer is not particularly limited as long as the insulation layer is made of a material having an insulation property. Examples of a material with insulation include resins such as epoxy resin, bismaleimide-triazine resin, polyimide resin, and polyphenylene ether resin. Only one of these resins may be used, or two or more of these resins may be used in combination.

When two or more insulation layers are present in the build-up layer, each of the insulation layers may be made of the same resin or may be made of different resin. The insulation layer included in the build-up layer and the core substrate may be made of the same resin or may be made of different resin. The build-up layer usually includes a via hole conductor for electrically connecting the layers.

The insulation layers included in the build-up layer may also contain a reinforcing material. Examples of the reinforcing material include insulation fabrics such as glass fiber, glass nonwovens, aramid nonwoven, aramid fiber, and polyester fiber. Only one type of reinforcing material may be used, or two or more types may be used in combination. An inorganic filler made of, for example, silica, barium sulfate, talc, clay, glass, calcium carbonate, or titanium oxide may be dispersed in the insulation layer included in the build-up layer. Only one type of the inorganic filler may be used, or two or more types may be used in combination.

As illustrated in FIG. 2, the optical waveguide 3 included in the optical circuit board 1 according to the embodiment extends from a peripheral edge of the wiring board 2 toward a center of the wiring board 2. Specifically, the optical waveguide 3 is located on a surface of the metal layer 21a present on a surface of the wiring board 2. FIG. 2 is an enlarged explanatory view for illustrating a cross section of a region X illustrated in FIG. 1. The optical waveguide 3 has a structure in which a lower cladding 31, a core 32, and an upper cladding 33 are layered in this order from the metal layer 21a side.

The lower cladding 31 included in the optical waveguide 3 is located on a first upper surface 2a (see FIG. 4) of the wiring board 2, specifically, on the surface of the metal layer 21a present on a surface of an optical waveguide forming region of the wiring board 2. The material forming the lower cladding 31 is not limited, and examples thereof include resins such as an epoxy resin and a silicone resin. Only one of these resins may be used, or two or more of these resins may be used in combination.

The upper cladding 33 included in the optical waveguide 3 is located so as to cover a second upper surface 31a (see FIG. 4) of the lower cladding 31 and the core 32. Similar to the lower cladding 31, the upper cladding 33 is made of resin such as the epoxy resin and the silicone resin. The lower cladding 31 and the upper cladding 33 may be made of the same material or different materials. The lower cladding 31 and the upper cladding 33 may have the same thickness or different thicknesses. Each of the lower cladding 31 and the upper cladding 33 has a thickness of, for example, 3 μm or more and 150 μm or less.

The core 32 included in the optical waveguide 3 extends on the second upper surface 31a of the lower cladding 31 and is a portion through which light having entered the optical waveguide 3 propagates. Specifically, a side surface of an optical transmission path 41 included in the optical component 4 and a side surface of the core 32 of the optical waveguide 3 face each other. The optical component 4 is mounted in the mounting region of the wiring board 2. By having such a configuration, an optical signal is transmitted and received between the core 32 and the optical transmission path 41. The material forming the core 32 is not limited and is set as appropriate in consideration of, for example, light permeability and wavelength characteristics of light propagating the core 32. Examples of the material include resins such as an epoxy resin or a silicone resin. The core 32 has a thickness of, for example, 3 μm or more and 50 μm or less.

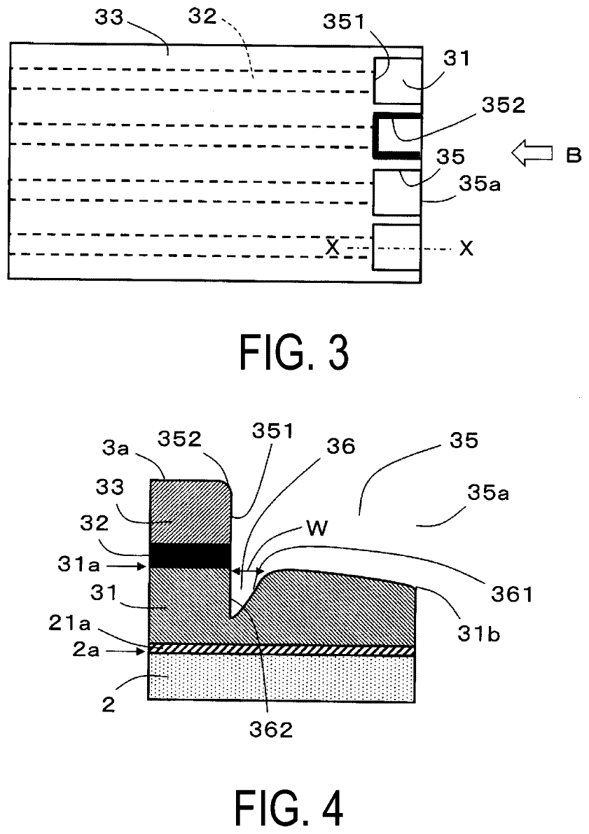

As illustrated in FIG. 3, the optical waveguide 3 includes a recessed portion 35 with the lower cladding 31 as a bottom surface and including a recessed portion opening 35a open to a third upper surface 3a (see FIG. 4) and a side surface of the optical waveguide 3. FIG. 3 is a plane perspective view of a region Y illustrated in FIG. 2 as viewed from a direction of an arrow A illustrated in FIG. 2. However, in FIG. 3, the optical connector 5a and the adhesive 34 are omitted. As illustrated in FIG. 3, one recessed portion 35 is provided for one core 32, and the size (width) of the recessed portion 35 is appropriately set according to the width of the core 32 and the size of the optical waveguide 3.

As illustrated in FIG. 4, the end surface of the core 32 is exposed on a first wall surface 351 of the wall surfaces forming the recessed portion 35, the first wall surface 351 being spaced apart from the peripheral edge of the wiring board 2. FIG. 4 is an enlarged explanatory view illustrating a cross section taken along a line X-X illustrated in FIG. 3. When the optical waveguide 3 is connected to the optical connector 5a, an optical signal is transmitted between the end surface of the core 32 and the optical connector 5a.

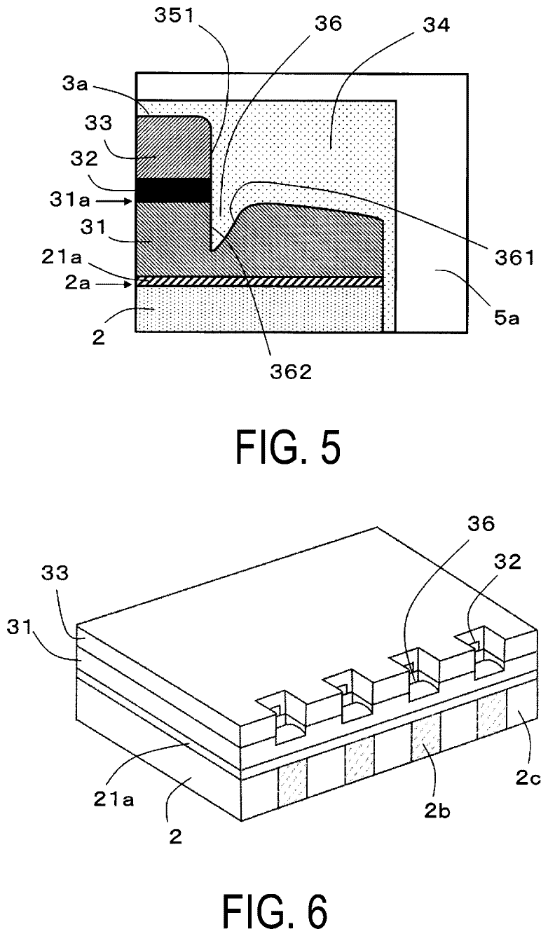

As illustrated in FIG. 4, a first groove 36 is located in the bottom surface of the recessed portion 35. The first groove 36 is located below the end surface of the core 32. As long as the first groove 36 is located below the end surface of the core 32, the first groove 36 does not need to be continuous with (flush with) the end surface of the core 32, and may be slightly displaced to the peripheral edge side of the wiring board 2. Since such a first groove 36 is located in the bottom surface of the recessed portion 35, as illustrated in FIG. 5, the first groove 36 is filled with the adhesive 34 connecting the optical waveguide 3 to the optical connector 5a. That is, an anchor effect is produced by the adhesive 34 in the first groove 36. Thus, the adhesive strength between the optical waveguide 3 and the optical connector 5a can be increased, and misalignment is less likely to occur at the connecting surface between the end surface of the optical waveguide 3 and the optical connector 5a. As a result, excellent connection reliability is exhibited between the optical waveguide 3 and the optical connector 5a, transmission loss is small, and the optical signal can be efficiently transmitted. FIG. 5 is an enlarged explanatory view illustrating a state where the recessed portion 35 illustrated in FIG. 3 is filled with the adhesive 34 and the optical connector 5a is connected.

The first groove 36 may be located continuously with the first wall surface 351, that is, as illustrated in FIG. 4, a third wall surface 362 of the first groove 36 may be flush with the first wall surface 351 of the recessed portion 35. With such a structure, the adhesive 34 easily enters the first groove 36, and the adhesive strength between the optical waveguide 3 and the optical connector 5a is easily increased. In the first groove 36, the second wall surface 361 is a wall surface located on the peripheral edge side of the wiring board 2, and the third wall surface 362 is a wall surface different from the second wall surface 361 (a wall surface located on the side opposite to the peripheral edge side of the wiring board 2).

As illustrated in FIG. 4, the first groove 36 need not extend through the lower cladding 31. When the first groove 36 extends through the lower cladding 31, laser is likely to hit the metal layer 21a to be reflected at the time of manufacturing the first groove 36, and there is a possibility that the end surface of the optical waveguide 3 cannot be formed into a predetermined shape. On the other hand, when the first groove 36 does not extend through the lower cladding 31, such reflection hardly occurs, and thus the end surface of the optical waveguide 3 is hardly affected by the laser and is easily formed into a predetermined shape. As a result, the end surface of the optical waveguide 3 (in particular, the end surface of the core 32) is less likely to be roughened by the reflected light of the laser, so that the transmission loss can be further reduced.

A width W of the first groove 36 illustrated in FIG. 4 is not limited, and may be, for example, 1 μm or more and 100 μm or less at an opening portion of the first groove 36. For example, as illustrated in FIG. 4, the width W of the first groove 36 may become wider from a bottom surface of the first groove 36 toward the opening portion of the first groove 36. When the first groove 36 has a structure in which the width becomes wider from the bottom surface toward the opening portion, as illustrated in FIG. 5, when the optical connector 5a is connected, the first groove 36 can be easily filled with the adhesive 34 up to the depth.

The wall surface of the first groove 36 may be substantially parallel or inclined toward the end surface of the optical waveguide 3. For example, the second wall surface 361 of the wall surfaces of the first groove 36 may be an inclined surface inclined toward the center side of the wiring board 2 from the opening portion of the first groove 36 to the bottom surface of the first groove 36. When the second wall surface 361 has such a structure, as illustrated in FIG. 5, when the optical connector 5a is connected, the first groove 36 can be easily filled with the adhesive 34 up to the depth.

In the recessed portion 35, an upper end portion 352 of an inner wall surface may be angular in an unprocessed state or may be chamfered to have an R shape. The upper end portion 352 of the inner wall surface of the recessed portion 35 is a range of a thick line portion in the recessed portion 35 illustrated in FIG. 3.

As illustrated in FIG. 4, the upper end portion 352 of the inner wall surface of the recessed portion 35 preferably has the R shape. When the upper end portion 352 of the inner wall surface of the recessed portion 35 has the R shape, breakage of the upper end portion (corner portion) due to contact with the optical connector 5a can be reduced. Thus, fragments generated by the breakage are less likely to contaminate the end surface of the optical waveguide 3 (the end surface of the core 32). As a result, excellent connection reliability is exhibited between the optical waveguide 3 and the optical connector 5a, transmission loss is small, and the optical signal can be further efficiently transmitted.

In the bottom portion of the recessed portion 35, an end portion 31b on the peripheral edge side of the wiring board 2 is angular in FIG. 4, but the end portion 31b may be chamfered to have an R shape. When the end portion 31b of the recessed portion 35 has the R shape, breakage of the end portion (corner portion) due to contact with the optical connector 5a can be reduced, similar to the case in which the upper end portion 352 of the inner wall surface has the R shape.

The bottom portion of the recessed portion 35 may be a flat surface or a curved surface. The bottom portion of the recessed portion 35 preferably has the curved surface. when the bottom portion of the recessed portion 35 has the curved surface, the contact area between the bottom portion of the recessed portion 35 and the adhesive 34 is increased, and thus the adhesive strength between the optical waveguide 3 and the optical connector 5a is easily increased.

When the bottom portion of the recessed portion 35 has the curved surface, a portion having the greatest height from the wiring board 2 is preferably provided between the first groove 36 and the recessed portion opening 35a. That is, it means that the maximum point of the bottom portion is located on the peripheral edge side of the wiring board 2 than the second wall surface 361 of the first groove 36. When the portion having the greatest height from the wiring board 2 is provided between the first groove 36 and the recessed portion opening 35a, the adhesive 34 is fixed on the second wall surface 361. Thus, the adhesive strength between the optical waveguide 3 and the optical connector 5a can be increased even when a stress is applied in the end surface direction. For example, a structure may be such that the portion having the greatest height from the wiring board 2 is located at a boundary portion between the second wall surface 361 of the first groove and the bottom portion of the recessed portion 35, and is inclined such that the bottom portion becomes lower toward the recessed portion opening 35a.

An arithmetic average roughness of the end surface of the wiring board 2 is not limited. On the end surface of the wiring board 2, as illustrated in FIG. 6, an arithmetic average roughness of a first end surface 2b located below the recessed portion opening 35a may be larger than an arithmetic average roughness of a second end surface 2c located other than below the recessed portion opening 35a. FIG. 6 is a perspective view as viewed from a direction of an arrow B illustrated in FIG. 3. The arithmetic average roughness of the first end surface 2b may be, for example, 10 nm or more and 1000 nm or less. The arithmetic average roughness of the second end surface 2c may be, for example, 5 nm or more and 500 nm or less.

When the arithmetic average roughness of the first end surface 2b is larger than the arithmetic average roughness of the second end surface 2c, as illustrated in FIG. 5, the adhesive 34 connecting the optical waveguide 3 to the optical connector 5a can be further firmly fixed to the first end surface 2b by the anchor effect. Specifically, when a part of the adhesive 34 with which the recessed portion 35 is filled flows out to the first end surface 2b, the adhesive 34 flown out to the first end surface 2b can be more firmly fixed. As a result, the adhesive strength between the optical waveguide 3 and the optical connector 5a can be further increased.

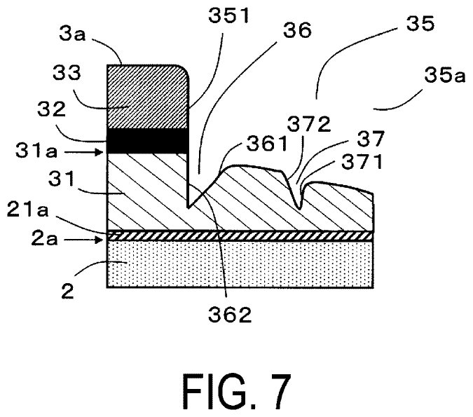

In the optical circuit board 1 according to the embodiment, as illustrated in FIG. 4, only the first groove 36 is located in the bottom surface of the recessed portion 35. As illustrated in FIG. 7, for example, in addition to the first groove 36, a second groove 37 may be further located in the bottom of the recessed portion 35. Similar to the first groove 36, the second groove 37 need not extend through the lower cladding 31. The reason is the same as the reason why the first groove 36 need not extend through the lower cladding 31.

When such a second groove 37 is located, the second groove 37 is also filled with the adhesive 34 connecting the optical waveguide 3 to the optical connector 5a, and the anchor effect is further exhibited. Thus, the adhesive strength between the optical waveguide 3 to the optical connector 5a can be further increased, and misalignment is further less likely to occur at the connecting surface between the end surface of the optical waveguide 3 and the optical connector 5a. As a result, excellent connection reliability is exhibited between the optical waveguide 3 and the optical connector 5a, transmission loss is small, and the optical signal can be further efficiently transmitted.

For example, at least one second groove 37 may be located substantially parallel to the first groove 36. Similar to the wall surface of the first groove 36, a wall surface of the second groove 37 may be substantially parallel or inclined toward the end surface of the optical waveguide 3. For example, a fourth wall surface 371 of the wall surfaces of the second groove 37 may be an inclined surface inclined toward the center side of the wiring board 2 from an opening portion of the second groove 37 to a bottom surface of the second groove 37. When the fourth wall surface 371 has such a structure, when the optical connector 5a is connected, the second groove 37 can be easily filled with the adhesive 34 up to the depth. The fourth wall surface 371 is a wall surface located on the peripheral edge side of the wiring board 2, and a fifth wall surface 372 is a wall surface different from the fourth wall surface 371 (a wall surface located on the side opposite to the peripheral edge side of the wiring board 2).

Alternatively, in at least a part of the second groove 37, the fifth wall surface 372 may be an inclined surface inclined toward the peripheral edge side of the wiring board 2 from the opening portion of the second groove 37 to the bottom surface of the second groove 37, and the fourth wall surface 371 may be substantially parallel to the end surface of the optical waveguide 3. When the wall surface of at least a part of the second groove 37 has such a structure, the anchor effect is further strongly exhibited. As a result, the adhesive 34 connecting the optical waveguide 3 to the optical connector 5a is further firmly fixed.

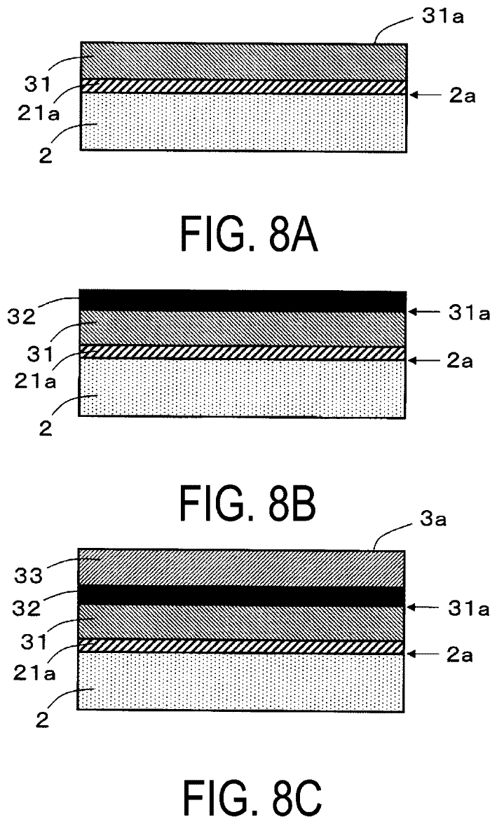

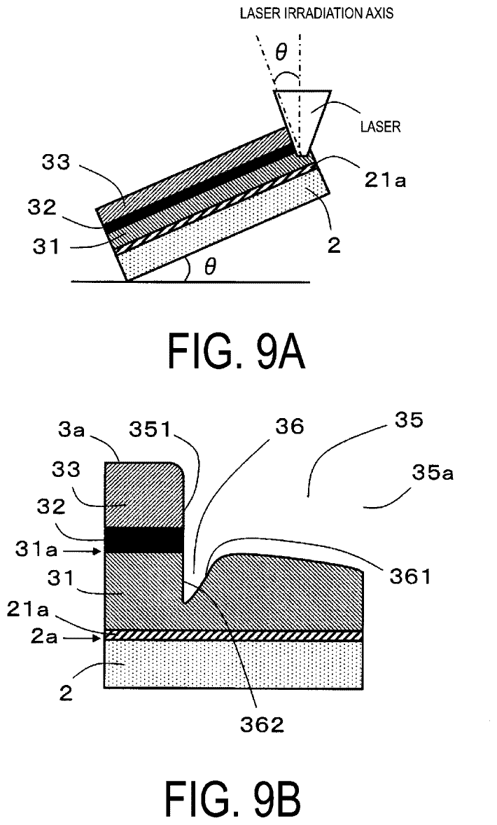

Next, a manufacturing method for the optical circuit board according to the present disclosure will be described with reference to FIGS. 8 and 9. FIGS. 8 and 9 are explanatory views each for illustrating a process of manufacturing the optical circuit board 1 according to the embodiment of the present disclosure. The manufacturing method for the optical circuit board 1 according to the embodiment includes the following steps (a) to (e).
(a) Step of preparing the wiring board 2 including the first upper surface 2a.
(b) Step of forming the optical waveguide 3 from the peripheral edge of the first upper surface 2a toward the center of the first upper surface 2a, the optical waveguide 3 including the lower cladding 31 including the second upper surface 31a, the core 32, and the upper cladding 33 and including the end portion at the peripheral edge of the wiring board 2.
(c) Step of preparing a laser device converging at a first angle θ with respect to an irradiation axis.
(d) Step of adjusting an angle between the third upper surface 3a of the optical waveguide 3 and a laser irradiation axis to 90 degrees+the first angle θ.
(e) Step of forming the recessed portion 35 with the lower cladding 31 as the bottom surface and including the recessed portion opening 35a continuously open to both the third upper surface 3a and the side surface of the optical waveguide 3 by irradiating the end portion of the optical waveguide 3 with the laser.

Step (a) is a step of preparing the wiring board 2 including the first upper surface 2a. The wiring board 2 is as described above, and thus detailed description thereof will be omitted.

Step (b) is a step of forming the optical waveguide 3 from the peripheral edge of the first upper surface 2a toward the center of the first upper surface 2a, the optical waveguide 3 including the lower cladding 31 including the second upper surface 31a, the core 32, and the upper cladding 33 and including the end portion at the peripheral edge of the wiring board 2. As illustrated in FIG. 8A, a resin film serving as a material of the lower cladding 31 is placed on the first upper surface 2a of the wiring board 2 (in FIG. 8A, the upper surface of the metal layer 21a). Examples of the resin film include a film formed of a resin such as an epoxy resin or a silicon resin as described in the lower cladding 31. The resin film has a thickness of, for example, 3 μm or more and 120 μm or less in consideration of the thickness of the lower cladding 31 to be obtained. Although the metal layer 21a is formed in FIG. 8A, the metal layer 21a may be omitted.

Next, as illustrated in FIG. 8B, the core 32 is formed on the second upper surface 31a of the lower cladding 31. A core resin is adhered so as to cover the second upper surface 31a. Examples of the core resin include a film formed of the resin such as the epoxy resin and the silicon resin, as described in the core 32. The core resin has a thickness of, for example, 3 μm or more and 60 μm or less in consideration of the thickness of the core 32 to be obtained. Next, a resist is formed on the upper surface of the core resin, and exposure and development are performed to cure the core resin, thereby forming the core 32.

Next, as illustrated in FIG. 8C, the upper cladding 33 is formed so as to cover the second upper surface 31a of the lower cladding 31 and the core 32. As a method of forming the upper cladding 33, for example, a resin film serving as a material of the upper cladding 33 is prepared. Examples of the resin film include a film formed of the resin such as the epoxy resin or the silicon resin as described in the upper cladding 33. The resin film has a thickness of, for example, 3 μm or more and 120 μm or less in consideration of the thickness of the upper cladding 33 to be obtained.

The resin film serving as the material of the upper cladding 33 is placed on the second upper surface 31a of the lower cladding 31 and the upper surface of the core 32. Thereafter, the resin film is heated and pressed, and as illustrated in FIG. 8C, the upper cladding 33 covering the second upper surface 31a of the lower cladding 31 and the core 32 is formed.

Step (c) is a step of preparing the laser device converging at the first angle θ with respect to the irradiation axis. The laser device is not limited, and examples of the laser device include an excimer laser device.

Step (d) is a step of adjusting an angle between the third upper surface 3a of the optical waveguide 3 and the laser irradiation axis to 90 degrees+the first angle θ. The angle between the third upper surface 3a and the laser irradiation axis can be adjusted by inclining a bottom surface of the wiring board 2 such that an angle between a pedestal and the bottom surface of the wiring board 2 becomes the first angle θ as illustrated in FIG. 9A. By thus adjusting the angle to perform laser irradiation, the end surface of the optical waveguide 3 is easily formed perpendicular to the wiring board 2. The first angle θ is preferably, for example, 1° or more and 15° or less.

Step (e) is a step of forming the recessed portion 35 with the lower cladding 31 as the bottom surface and including the recessed portion opening 35a continuously open to both the third upper surface 3a and the side surface of the optical waveguide 3 by irradiating the end portion of the optical waveguide 3 with the laser. In the step of forming the recessed portion 35, as illustrated in FIG. 9B, the end surface of the core 32 is exposed on the first wall surface 351 of the wall surfaces of the recessed portion 35, the first wall surface 351 being spaced apart from the peripheral edge of the wiring board 2, and the first groove 36 located continuously with the first wall surface 351 is formed in the bottom surface of the recessed portion 35 below the end surface of the core 32.

The intensity of the laser irradiation may be appropriately set in consideration of the thickness of the optical waveguide 3, the types of materials (resins) forming the lower cladding 31, the core 32, and the upper cladding 33, and the like. It is necessary to irradiate the laser such that the first groove 36 does not extend through the lower cladding 31. For example, the laser may be adjusted to such an intensity that the first groove 36 does not extend through the lower cladding 31, or the irradiation may be stopped before the first groove 36 extends through the lower cladding 31.

By inclining the bottom surface of the wiring board 2 such that the angle between the pedestal and the bottom surface of the wiring board 2 is the first angle θ as illustrated in FIG. 9A, the second wall surface 361 of the wall surfaces of the first groove 36 can be easily formed as an inclined surface inclined toward the center side of the wiring board 2 from the opening portion of the first groove 36 to the bottom surface of the first groove 36 as illustrated in FIG. 9B. Further, by inclining the bottom surface of the wiring board 2, the end surface of the wiring board 2 is also irradiated with the laser, so that the end surface can be roughened.

By such steps (a) to (e), the optical circuit board 1 according to an embodiment is obtained in which the end surface of the core 32 is exposed to the first wall surface 351 by providing the recessed portion 35 in the peripheral edge portion of the optical waveguide 3, and the first groove 36 located below the end surface of the core 32 is located in the bottom surface of the recessed portion 35.

As another manufacturing method for the optical circuit board according to the present disclosure, in the step (d), instead of inclining the bottom surface of the wiring board 2, the end surface of the wiring board 2 may be irradiated with the laser from an oblique direction. That is, the laser may be radiated obliquely so that the angle between the third upper surface 3a of the optical waveguide 3 and the laser irradiation axis is 90 degrees+the first angle θ.

The optical component mounting structure of the present disclosure will be described. As illustrated in FIG. 1, according to an embodiment of the present disclosure, the optical component mounting structure 10 has a structure in which the optical component 4 and an electronic component 6 are mounted on the optical circuit board 1 according to an embodiment. The optical component 4 mounted on the optical component mounting structure 10 according to the embodiment includes the optical transmission path 41. Examples of the optical component 4 including the optical transmission path 41 include a silicon photonics device. Examples of the electronic component 6 include an application specific integrated circuit (ASIC) and a driver IC.

As illustrated in FIG. 2, the optical component 4 is electrically connected to the wiring board 2. Specifically, the optical component 4 is electrically connected to pads 21b located in a mounting region (mounting region of the optical component) of the wiring board 2. via solders 7. The pad 21b is part of the electrical conductor layer positioned on the upper surface of the wiring board 2.

As an example of the optical component 4, a silicon photonics device will be described. The silicon photonics device is, for example, a type of optical component including the optical transmission path 41 in which silicon (Si) is used as a core and silicon dioxide (SiO2) is used as a clad. The silicon photonics device includes a Si waveguide as the optical transmission path 41, and further includes a passivation film, a light source unit, a light detector, and the like, which are not illustrated. As described above, the optical transmission path 41 (Si waveguide 41) is located so as to face the core 32 included in the optical waveguide 3 at one end portion of the optical waveguide 3.

For example, an electrical signal from the wiring board 2 is propagated to the light source unit included in the optical component 4 (silicon photonics device) via the solder 7. The light source unit emits light upon receiving the propagated electrical signal. The emitted optical signal is propagated to the optical fiber 5 connected via the optical connector 5a, through the optical transmission path 41 (Si waveguide 41) and the core 32.

An embodiment of the present disclosure has been described above. However, the invention according to the present disclosure is not limited to the above-described embodiment, and various changes or improvements can be made within the scope of the present disclosure described in (1), (14), and (15) below.
(1) An optical circuit board according to the present disclosure includes a wiring board including a first upper surface and an optical waveguide located on a the first upper surface and extending from a peripheral edge of the wiring board toward a center of the wiring board. The optical waveguide includes a lower cladding, a core, and an upper cladding in this order from the first upper surface side. The core extends on a second upper surface of the lower cladding, and the upper cladding covers the second upper surface and the core. The optical waveguide includes a recessed portion with the lower cladding as a bottom surface and including a recessed portion opening open to a third upper surface and a side surface of the optical waveguide. An end surface of the core is exposed on a first wall surface of wall surfaces of the recessed portion, the first wall surface being spaced apart from the peripheral edge of the wiring board. A first groove located below the end surface of the core is located in the bottom surface of the recessed portion.
(14) An optical component mounting structure according to the disclosure includes the optical circuit board described above and an optical component mounted on the optical circuit board.
(15) A manufacturing method for an optical circuit board according to the present disclosure includes a step of preparing the wiring board including the first upper surface, a step of forming the optical waveguide from the peripheral edge of the first upper surface toward a center of the first upper surface, the optical waveguide including the lower cladding including the second upper surface, the core, and the upper cladding and including an end portion at the peripheral edge of the wiring board, a step of preparing a laser device converging at a first angle with respect to an irradiation axis, a step of adjusting an angle between a third upper surface of the optical waveguide and a laser irradiation axis to 90 degrees+the first angle, and a step of forming a recessed portion with the lower cladding as a bottom surface and including a recessed portion opening continuously open to both the third upper surface and a side surface of the optical waveguide by irradiating an end portion of the optical waveguide with the laser. In the step of forming the recessed portion, the end surface of the core is exposed on the first wall surface of the wall surfaces of the recessed portion, the first wall surface being spaced apart from the peripheral edge of the wiring board, and a first groove located continuously with the first wall surface is formed in the bottom surface of the recessed portion below the end surface of the core.

With respect to the embodiment of the present disclosure, the embodiments described in (2) to (13) and (16) below are further disclosed.
(2) In the optical circuit board according to (1) described above, the first groove does not extend through the lower cladding.
(3) In the optical circuit board according to (1) or (2) described above, the wiring board further includes a metal layer on the first upper surface, and the optical waveguide is located on an upper surface of the metal layer.
(4) In the optical circuit board according to any one of (1) to (3) described above, a width of the first groove becomes wider from a bottom surface of the first groove toward an opening portion of the first groove.
(5) In the optical circuit board according to any one of (1) to (4) described above, a second wall surface of wall surfaces of the first groove, the second wall surface being located on the peripheral edge side of the wiring board, is an inclined surface inclined toward the center side of the wiring board from the opening portion of the first groove to the bottom surface of the first groove.
(6) In the optical circuit board according to any one of (1) to (5) described above, on the end surface of the wiring board, an arithmetic average roughness of a first end surface located below the recessed portion opening is larger than an arithmetic average roughness of a second end surface located other than below the recessed portion opening.
(7) In the optical circuit board according to any one of (1) to (6) described above, an upper end portion of an inner wall surface of the recessed portion has an R shape.
(8) In the optical circuit board according to any one of (1) to (7) described above, a bottom surface of the recessed portion has a curved surface.
(9) In the optical circuit board according to (8) described above, the curved surface includes, between the first groove and the recessed portion opening, a portion having the greatest height from the wiring board.
(10) In the optical circuit board according to any one of (1) to (9) described above, in the bottom surface of the recessed portion, an end portion on the recessed portion opening side has an R shape.
(11) In the optical circuit board according to any one of (1) to (10) described above, a second groove is further located in the bottom of the recessed portion.
(12) In the optical circuit board according to (11) described above, the second groove does not extend through the lower cladding.
(13) In the optical circuit board according to any one of (1) to (12) described above, the first groove is located continuously with the first wall surface.
(16) In the manufacturing method according to (15), the wiring board further includes a metal layer on the first upper surface, and the lower cladding is formed on the metal layer.

### REFERENCE SIGNS

1 Optical circuit board
2 Wiring board
2a First upper surface
2b First end surface
2c Second end surface
21a Metal layer
21b Pad
3 Optical waveguide
3a Third upper surface
31 Lower cladding
31a Second upper surface
32 Core
33 Upper cladding
34 Adhesive
35 Recessed portion
35a Recessed portion opening
351 First wall surface
352 Upper end portion
36 First groove
361 Second wall surface
362 Third wall surface
37 Second groove
371 Fourth wall surface
372 Fifth wall surface
4 Optical component
41 Optical transmission path (silicon waveguide (Si waveguide))
5 Optical fiber
5a Optical connector
6 Electronic component
7 Solder
10 Optical component mounting structure

1. An optical circuit board comprising:
a wiring board comprising a first upper surface; and
an optical waveguide located on the first upper surface and extending from a peripheral edge of the wiring board toward a center of the wiring board, wherein
the optical waveguide comprises
a lower cladding,
a core, and
an upper cladding in this order from the first upper surface side,
the core extends on the second upper surface of the lower cladding, the upper cladding covers the second upper surface and the core,
the optical waveguide comprises a recessed portion with the lower cladding as a bottom surface and comprising a recessed portion opening open to a third upper surface and a side surface of the optical waveguide,
an end surface of the core is exposed on a first wall surface of wall surfaces of the recessed portion, the first wall surface being spaced apart from a peripheral edge of the wiring board, and
a first groove located below the end surface of the core is located in the bottom surface of the recessed portion.

2. The optical circuit board according to claim 1, wherein
the first groove does not extend through the lower cladding.

3. The optical circuit board according to claim 1, wherein
the wiring board further comprises a metal layer on the first upper surface, and
the optical waveguide is located on an upper surface of the metal layer.

4. The optical circuit board according to claim 1, wherein
a width of the first groove becomes wider from a bottom surface of the first groove toward an opening portion of the first groove.

5. The optical circuit board according to claim 1, wherein
a second wall surface, located on the peripheral edge side of the wiring board, of wall surfaces of the first groove is an inclined surface inclined toward the center side of the wiring board from the opening portion of the first groove to the bottom surface of the first groove.

6. The optical circuit board according to claim 1, wherein
on the end surface of the wiring board, an arithmetic average roughness of a first end surface located below the recessed portion opening is larger than an arithmetic average roughness of a second end surface located other than below the recessed portion opening.

7. The optical circuit board according to claim 1, wherein
an upper end portion of an inner wall surface of the recessed portion has an R shape.

8. The optical circuit board according to claim 1, wherein
a bottom surface of the recessed portion has a curved surface.

9. The optical circuit board according to claim 8, wherein
the curved surface comprises, between the first groove and the recessed portion opening, a portion having a greatest height from the wiring board.

10. The optical circuit board according to claim 1, , wherein
in the bottom surface of the recessed portion, an end portion on the recessed portion opening side has an R shape.

11. The optical circuit board according to claim 1, wherein
a second groove is further located in the bottom of the recessed portion.

12. The optical circuit board according to claim 11, wherein the second groove does not extend through the lower cladding.

13. The optical circuit board according to claim 1, wherein
the first groove is located continuously with the first wall surface.

14. An optical component mounting structure comprising:
the optical circuit board according to claim 1; and
an optical component mounted on the optical circuit board.

15. A manufacturing method for an optical circuit board, the method comprising:
preparing a wiring board comprising a first upper surface;
forming an optical waveguide from a peripheral edge of the first upper surface toward a center of the first upper surface. the optical waveguide comprising a lower cladding comprising a second upper surface, a core, and an upper cladding and comprising an end portion at a peripheral edge of the wiring board;
preparing a laser device converging at a first angle with respect to an irradiation axis;
adjusting an angle between a third upper surface of the optical waveguide and a laser irradiation axis to 90 degrees+the first angle; and
forming a recessed portion with the lower cladding as a bottom surface and comprising a recessed portion opening continuously open to both the third upper surface and a side surface of the optical waveguide by irradiating the end portion of the optical waveguide with the laser, wherein
during the formation of the recessed portion, an end surface of the core is exposed on a first wall surface of wall surfaces of the recessed portion that is spaced apart from the peripheral edge of the wiring board, and a first groove located continuously with the first wall surface is formed in the bottom surface of the recessed portion below the end surface of the core.

16. The manufacturing method for an optical circuit board according to claim 15, wherein
the wiring board further comprises a metal layer on the first upper surface, and the lower cladding is formed on the metal layer.
